(19) United States
(12) Patent Application Publication
(10) Pub. No.: US 2014/0373903 A1
(43) Pub. Date: Dec. 25, 2014

(54) SOLAR CELL MODULE

(71) Applicant: SANYO ELECTRIC CO., LTD., OSAKA (JP)

(72) Inventors: Haruhisa HASHIMOTO, Osaka (JP); Yousuke ISHII, Osaka (JP)

(21) Appl. No.: 14/484,315

(22) Filed: Sep. 12, 2014

Related U.S. Application Data
(63) Continuation of application No. PCT/JP2013/056674, filed on Mar. 11, 2013.

(30) Foreign Application Priority Data
Mar. 16, 2012 (JP) 2012-060316

(51) Int. Cl. H01L 31/05; H01L 31/048

(52) U.S. Cl. CPC H01L 31/0508; H01L 31/048
USPC 136/251; 136/244

(57) ABSTRACT

A solar cell module includes a plurality of solar cells and a wiring member attached to surfaces of the adjacent solar cells on one side. The wiring member electrically connects the adjacent solar cells electrically and includes an insulation sheet and a conductive layer disposed on the insulation sheet. A length of a portion of the wiring member located between the adjacent solar cells is greater than a distance between the adjacent solar cells.

### CROSS REFERENCE TO RELATED APPLICATIONS

This application is a continuation application of International Application No. PCT/JP2013/056674, filed on Mar. 11, 2013, entitled “SOLAR CELL MODULE”, which claims priority based on Article 8 of Patent Cooperation Treaty from prior Japanese Patent Applications No. 2012-060316, filed on Mar. 16, 2012, the entire contents of which are incorporated herein by reference.

### BACKGROUND

The invention relates to a solar cell module.

A solar cell module including a plurality of back contact solar cells connected to each other by wiring members has been known as a solar cell module capable of realizing improved output characteristics (see Patent Document 1, for example).

Patent Document 1: Japanese Patent Application Publication No. 2009-266848

### SUMMARY OF THE INVENTION

There is a demand for improvement in endurance for repeated increases and decreases in the temperature of the solar cell module.

One aspect of the invention provides a solar cell module with improved endurance for the repeated increases and decreases in the temperature.

A solar cell module according to an embodiment includes a plurality of solar cells and a wiring member. The wiring member is attached to surfaces of the adjacent solar cells on one side. The wiring member electrically connects the adjacent solar cells. The wiring member includes an insulation sheet and a conductive layer disposed on the insulation sheet. A length of a portion of the wiring member located between the adjacent solar cells is greater than a distance between the adjacent solar cells.

The embodiments above provide a solar cell module with improved endurance for repeated increases and decreases in the temperature.

### BRIEF DESCRIPTION OF THE DRAWINGS

FIG. 1 is a schematic cross-sectional view of a solar cell module according to an embodiment.

FIG. 2 is a schematic rear view of a solar cell of an embodiment.

FIG. 3 is a schematic side view of a wiring member of an embodiment.

FIG. 4 is a schematic side view of a solar cell string of a first modified example.

FIG. 5 is a schematic side view of a solar cell string of a second modified example.

FIG. 6 is a schematic side view of a solar cell string of a third modified example.

FIG. 7 is a schematic cross-sectional view of a solar cell module of a fourth modified example.

### EMBODIMENTS

Hereinafter, examples of preferred embodiments are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated schematically, and the dimensional ratio and the like of objects depicted in the drawings are different from those of actual objects in some cases. The dimensional ratio and the like of objects are also different among the drawings in some cases. The specific dimensional ratio and the like of objects should be determined with the following description taken into consideration.

### First Embodiment

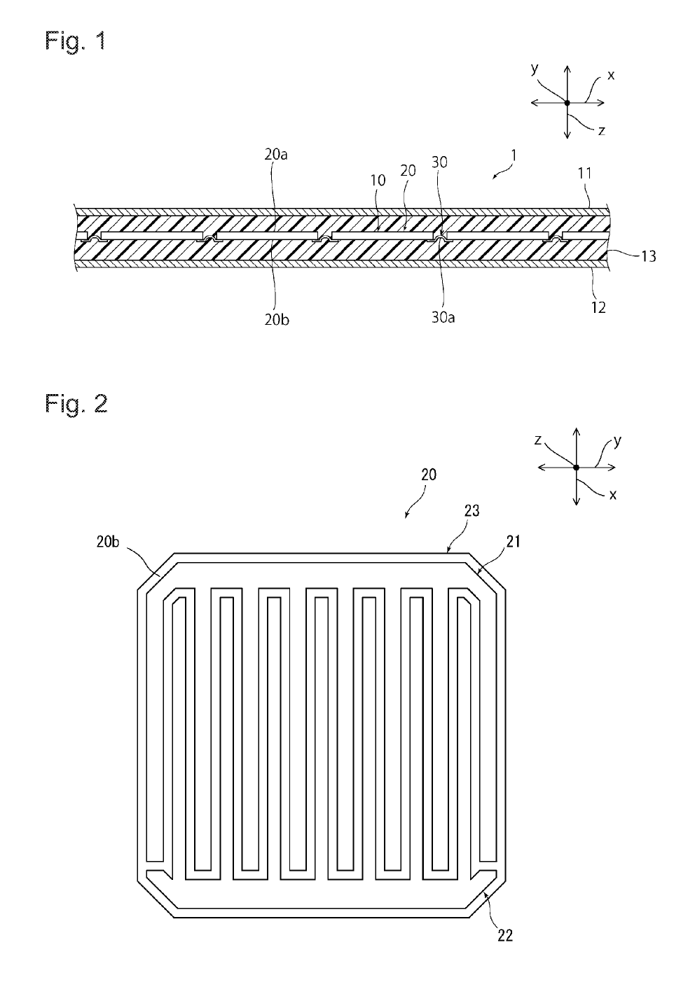

As illustrated in FIG. 1, solar cell module 1 includes solar cell string 10. Solar cell string 10 is disposed between first protection member 11 located on a light-receiving surface 20a side and second protection member 12 located on a rear surface 20b side. Sealing material 13 is provided between first protection member 11 and second protection member 12. Solar cell string 10 is sealed by sealing material 13.

First protection member 11 can be made of, for example, a glass substrate, a resin substrate, or the like. Second protection member 12 can be made of, for example, a resin sheet, a resin sheet internally including a metal foil, a glass substrate, a resin substrate, or the like. Sealing material 13 can be made of, for example, a resin such as ethylene-vinyl acetate copolymer (EVA), polyvinyl butyral (PVB), polyethylene (PE), and polyurethane (PU).

Solar cell string 10 includes a plurality of solar cells 20 which are arranged at intervals in a first direction (an x-axis direction). A plurality of solar cells 20 are electrically connected to each other by wiring members 30. Specifically, wiring member 30 electrically connects solar cells 20 that are adjacent to each other in the x-axis direction. Wiring member 30 is attached to rear surfaces 20b of solar cells 20 adjacent in the x-axis direction. Solar cells 20 and wiring member 30 can be attached together, for example, by using a resin adhesive, a resin adhesive containing a conductive material, solder, or the like.

In the embodiment, solar cells 20 are back contact solar cells in which first and second electrodes 21 and 22 are provided on rear surfaces 20b out of light-receiving and rear surfaces 20a, 20b. However, in the invention, solar cells are not limited to the back contact solar cells.

As illustrated in FIG. 2, solar cell 20 includes photoelectric conversion body 23. Photoelectric conversion body 23 is configured to generate photogenerated carriers or the like upon receipt of light. Photoelectric conversion body 23 may include, for example, a semiconductor substrate having one conductive type, a first semiconductor layer having another conductive type and disposed on part of one principal surface of the semiconductor substrate, and a second semiconductor layer having the one conductive type and disposed on at least part of a portion on the one principal surface of the semiconductor substrate where the first semiconductor layer is not disposed. Otherwise, photoelectric conversion body 23 may be formed from a semiconductor substrate, for example, provided with a p-type dopant diffused region and an n-type dopant diffused region which are located to be exposed to one principal surface. In either case, solar cell 20 includes first and second electrodes 21 and 22 on the rear surface side. Here, one of first and second electrodes 21 and 22 is an electrode which collects majority carriers and the other electrode is an electrode which collects minority carriers.

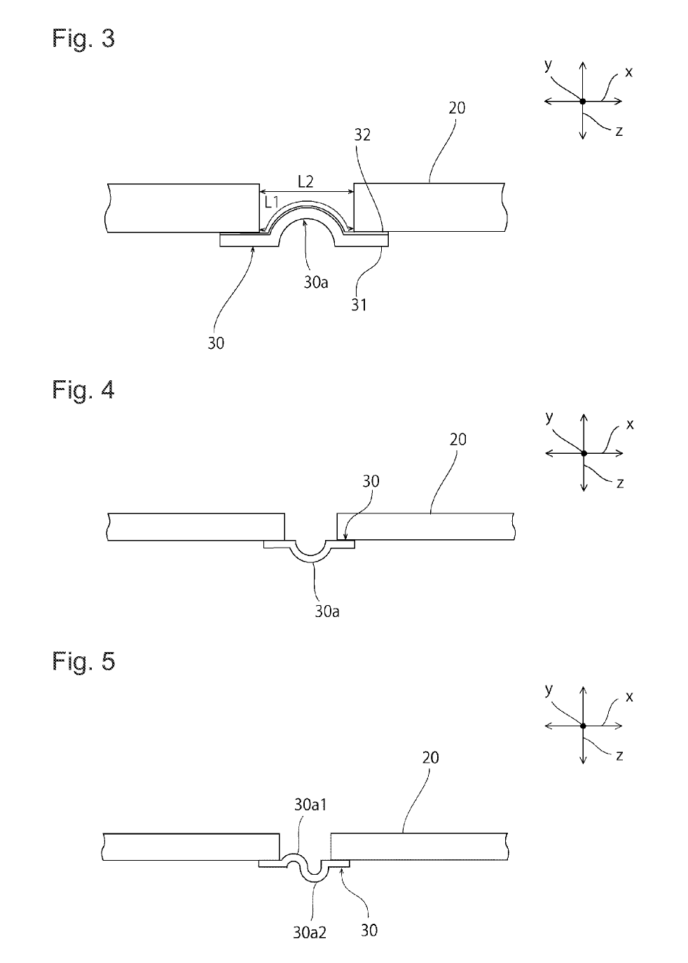

As illustrated in FIG. 3, wiring member 30 includes insulation sheet 31 and conductive layer 32. It is preferable that insulation sheet 31 be flexible. Insulation sheet 31 can be made of a resin sheet, for example. The thermal expansion coefficient of insulation sheet 31 is different from the thermal expansion coefficient of sealing material 13. The thermal expansion coefficient of insulation sheet 31 may be either greater or smaller than the thermal expansion coefficient of sealing material 13.

Conductive layer 32 is disposed on insulation sheet 31. Adjacent solar cells 20 are electrically connected by conductive layer 32. Conductive layer 32 can be made of an appropriate conductive material such as a metal.

A portion of wiring member 30 located between adjacent solar cells 20 includes a curved portion or a bent portion. Specifically, in the embodiment, the portion of wiring member 30 located between adjacent solar cells 20 includes curved portion 30a. Accordingly, length L1 of the portion of wiring member 30 located between adjacent solar cells 20 is greater than distance L2 between adjacent solar cells 20. For this reason, even when distance L2 between adjacent solar cells 20 is increased due to a rise of the temperature of solar cell module 1, a stress is unlikely to be applied between wiring member 30 and each solar cell 20 since wiring member 30 is expandable and contractible in the x-axis direction. Hence, wiring member 30 and solar cells 20 are unlikely to be detached. Thus, it is possible to realize solar cell module 1 with improved endurance for repeated increases and decreases in the temperature. From the viewpoint of further improving the endurance for the repeated increases and decreases in the temperature, it is preferable that length L1 be at least 1.1 times greater than distance L2. In addition, when wiring member 30 is flexible, the stress is even less likely to be applied between wiring member 30 and each solar cell 20. As a consequence, it is possible to realize solar cell module 1 with further improved endurance for repeated increases and decreases in the temperature.

In particular, when the thermal expansion coefficient of sealing material 13 is greater than the thermal expansion coefficient of wiring member 30, it is preferable to satisfy L1>L2 since distance L2 between adjacent solar cells 29 becomes greater than an amount of thermal expansion of wiring member 30 as a consequence of thermal expansion of sealing material 13.

Curved portion 30a may be formed to project inward of solar cells 20. In this case, the thickness of solar cell string 10 can be kept small. Accordingly, it is possible to suppress a change in thickness of the solar cell module, which is sealed between first protection member 11 and second protection member 12 by using sealing material 13. Here, to project inward of solar cells 20 means to have a shape projecting in a direction from rear surfaces 20b toward light-receiving surfaces 20a of solar cells 20.

Modified examples of the embodiment are described below. In the following descriptions, the members having virtually the same functions as those in the first embodiment are designated by the same reference numerals and explanations thereof are omitted.

As illustrated in FIG. 4, curved portion 30a is provided to project outward of solar cells 20. This suppresses a reduction in output performance of solar cell module 1 attributed to undesirable contact between conductive layer 32 and photoelectric conversion body 23. Here, to project outward of solar cells 20 means to have a shape projecting in a direction from light-receiving surfaces 20a toward rear surfaces 20b of solar cells 20.

As illustrated in FIG. 5, the portion of wiring member located between adjacent solar cells 20 may include a plurality of curved portions 30a1 and 30a2. Curved portion 30a1 is provided to project toward solar cells 20 while curved portion 30a2 is provided to project away from solar cells 20. Thereby, it is possible to secure sufficient length L1 while suppressing amounts of projection toward solar cells 20 and away from solar cells 20 of the respective curved portions as compared to a case of providing just one curved portion. Accordingly, the design freedom for length L1 can be enhanced while suppressing the thickness of the solar cell module. Here, the number of the curved portions is not limited to two, and three or more curved portions may be provided.

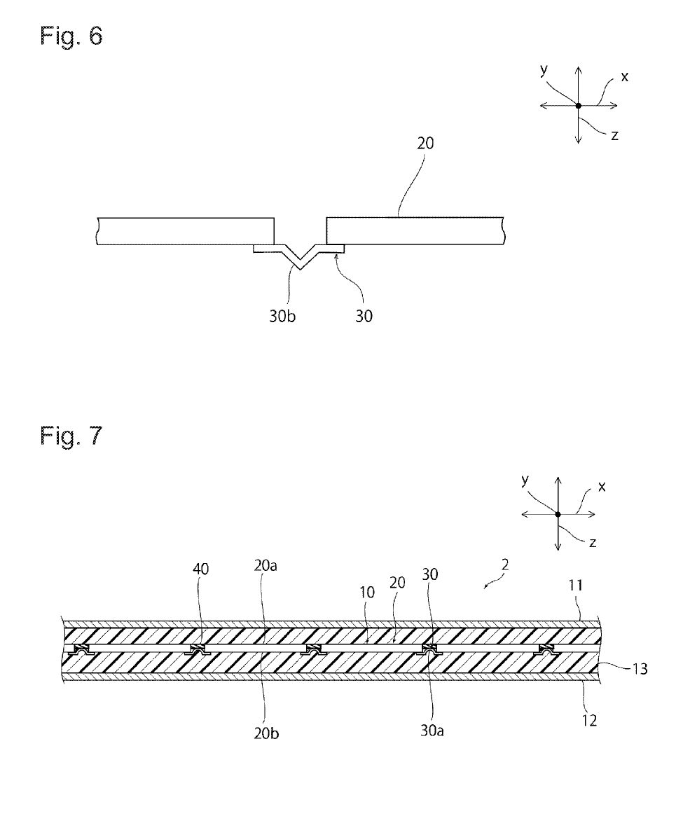

As illustrated in FIG. 6, the portion of wiring member 30 located between adjacent solar cells 20 may include at least one bent portion 30b. Bent portion 30b is provided to project away from solar cells 20. Thus, application of a stress between wiring member 30 and each solar cell 20 can be suppressed only by bending wiring member 30. Here, the bent portion may be provided to project toward solar cells 20.

The portion of wiring member 30 located between adjacent solar cells 20 may include both a curved portion and a bent portion.

Solar cell module 2 includes a plurality of solar cells 20, and therefore includes a plurality of wiring members 30 as well. Curved portions 30a1 and 30a2 and bent portions 30b of wiring members 30 to be provided to solar cell module 2 do not always have to be formed into the same shape. For example, solar cell module 2 may include a mixture of wiring members 30 illustrated in FIG. 3 and wiring members 30 illustrated in FIG. 4. In the meantime, it is not indispensable that every wiring member 30 provided to solar cell module 2 should include any one of curved portions 30a1 and 30a2 and bent portion 30b.

Solar cell module 2 illustrated in FIG. 7 further includes resin members 40 disposed between adjacent solar cells 20. Resin member 40 has the thermal expansion coefficient smaller than the thermal expansion coefficient of sealing material 13. For this reason, the distance between adjacent solar cells 20 is less likely to change in the case of a change in temperature of solar cell module 2. Hence, wiring members 30 and solar cells 20 are less likely to be detached. Thus, it is possible to further improve the endurance for repetition of increase and decrease in temperature.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell module comprising:
a plurality of solar cells; and
a wiring member attached to surfaces of the adjacent solar cells on one side, and configured to electrically connect the adjacent solar cells, wherein
the wiring member includes an insulation sheet, and a conductive layer provided on the insulation sheet, and
a length of a portion of the wiring member located between the adjacent solar cells is greater than a distance between the adjacent cells.

2. The solar cell module according to claim 1, wherein
the length of a portion of the wiring member located between the adjacent solar cells is more than 1.1 times greater than a distance between the adjacent cells.

3. The solar cell module according to claim 1, wherein
the wiring member is flexible.

4. The solar cell module according to claim 1, wherein
the portion of the wiring member located between the adjacent solar cells includes a curved portion or a bent portion.

5. The solar cell module according to claim 4, wherein
the at least one of the curved portion and the bent portion includes a portion projecting outward of the solar cells.

6. The solar cell module according to claim 4, wherein
the at least one of the curved portion and the bent portion includes a portion projecting inward of the solar cells.

7. The solar cell module according to claim 5, wherein
the at least one of the curved portion and the bent portion includes a portion projecting inward of the solar cells.

8. The solar cell module according to claim 1, further comprising
a sealing material configured to seal the plurality of solar cells and the wiring member.

9. The solar cell according to claim 8, wherein
a thermal expansion coefficient of the sealing material is greater than a thermal expansion coefficient of the insulation sheet.

10. The solar cell according to claim 8, wherein
a thermal expansion coefficient of the sealing material is smaller than a thermal expansion coefficient of the insulation sheet.

11. The solar cell according to claim 1, wherein
each solar cell comprises first and second electrodes located on the surface on the one side.

12. The solar cell according to claim 1, wherein
the insulation sheet is flexible.

13. The solar cell according to claim 1, wherein
the insulation sheet includes a resin sheet.

14. The solar cell according to claim 7, further comprising
a resin member disposed between the adjacent solar cells.

15. The solar cell according to claim 14, wherein
a thermal expansion coefficient of the resin member is smaller than a thermal expansion coefficient of sealing material.
